(19) United States
(12) Patent Application Publication
(10) Pub. No.: US 2011/0050257 A1
(43) Pub. Date: Mar. 3, 2011

(54) Moisture meter

(76) Inventors: John Ashworth, County Dublin (IE); John Fallon, County Dublin (IE); James McIlroy, County Dublin (IE)

(21) Appl. No.: 12/805,880

(22) Filed: Aug. 23, 2010

(30) Foreign Application Priority Data
Aug. 27, 2009 (IE) 2009/0652

(51) Int. Cl. G01R 27/26

(52) U.S. Cl. 324/689

(57) ABSTRACT

A moisture meter (1) has an elongate probe (3) supporting at least one pair of electrodes (5, 6), and being configured for insertion into bulk material (C). There is a transmitter (50) for driving an electrode (5, 6) and a detector (51) for receiving current signals of an electrode. A controller (54) controls drive of the electrodes (5, 6) and processes detected signals to provide a moisture reading. There are at least two axially separated radial spacers (7, 8) having ridges (30) extending radially to an extent greater than the electrodes, to centralise the probe and to provide a gap between the electrodes and bulk material when the probe is inserted in a hole (H) in the bulk material. The spacers (7, 8) are configured to provide a low friction fit within a hole in the bulk material. There is a leading spacer (7) on a leading side of a first electrode (5) and a trailing spacer (8) at a trailing side of a second electrode (6). The transmitter (50) is connected to an electrode by a wire running along a groove (22) in a probe former (21), and the detector (51) is connected to an electrode by a wire running along a diametrically opposed groove (22).

### FIELD OF THE INVENTION

The invention relates to moistures meters.

### PRIOR ART DISCUSSION

It is known to provide a moisture meter which has capacitive electrodes for surface contact at desired locations. Depending on capacitive coupling between the electrodes, an output is generated which indicates humidity of the material.

While such instruments are very effective and convenient to use, there are situations where it is needed to monitor moisture within the body of the material, well beneath the surface. For this application, it is known to drill a blind hole, insert a relative humidity probe and leave the probe in situ for a period of about 72 hours. A problem with this arrangement is that the relative humidity sensing components are delicate and prone to corrosion over time due to the ambient conditions within the blind holes during the test time.

GB2334586 describes a moisture sensing probe having helically wound conductors.

GB1419235 describes a measuring probe which is inserted into the bulk material and has cylindrical electrodes.

The invention is directed towards providing an improved moisture meter for concrete or other bulk materials.

### SUMMARY OF THE INVENTION

According to the invention, there is provided a moisture meter comprising:
an elongate probe supporting at least one pair of electrodes, and being configured for insertion into bulk material;
a transmitter for driving an electrode;
a detector for receiving current signals of an electrode;
a controller for controlling drive of the electrodes and for processing detected signals to provide a moisture reading; and
wherein there are at least two axially separated radial spacers having formations extending radially to an extent greater than the electrodes, the spacer formations being configured to centralise the probe and to provide a gap between the electrodes and bulk material when the probe is inserted in a hole in the bulk material.

In one embodiment, the spacer formations are configured to provide a low friction fit within a hole in the bulk material.

In one embodiment, the formations are ridges extending substantially parallel to an axis of the probe.

In one embodiment, there are at least four ridges on each spacer.

In another embodiment, there is a leading spacer on a leading side of a first electrode and a trailing spacer at a trailing side of a second electrode.

In one embodiment, the transmitter is connected to an electrode by a wire running along a groove in the probe.

In a further embodiment, the detector is connected to an electrode by a wire running along a groove in the probe.

In one embodiment, the grooves are diametrically opposed.

In one embodiment, the probe comprises a stalk and the electrodes and the spacers are mounted on the stalk.

In a further embodiment, the controller drives the electrodes with a constant frequency and constant amplitude signal.

In one embodiment, the drive signal is a unity mark space square wave.

In one embodiment, the controller comprises a half wave rectifier/amplifier to detect and amplify received AC current and output a voltage proportional to moisture content.

In another embodiment, the controller comprises a logarithmic amplifier to provide a linear output.

In one embodiment, the electrodes are of copper foil material.

In one embodiment, the electrodes are on a former on the probe.

In one embodiment, the former axially abuts a spacer having a shoulder configuration to cover over a hole into which the probe is inserted.

In one embodiment, the electrodes are conductors on a printed circuit board which is flexible and is wrapped around a former.

In one embodiment, the electrodes include a protective insulation material coating.

### DETAILED DESCRIPTION OF THE INVENTION

### BRIEF DESCRIPTION OF THE DRAWINGS

The invention will be more clearly understood from the following description of some embodiments thereof, given by way of example only with reference to the accompanying drawings in which:

FIG. 1 is a plan view of a moisture meter of the invention;

FIGS. 2 and 3 show parts of the meter in more detail;

FIG. 4 is a diagram showing the meter in use and also showing the electronic circuits in block diagram form; and

FIG. 5 is a diagram illustrating an alternative electrode arrangement.

### DESCRIPTION OF THE EMBODIMENTS

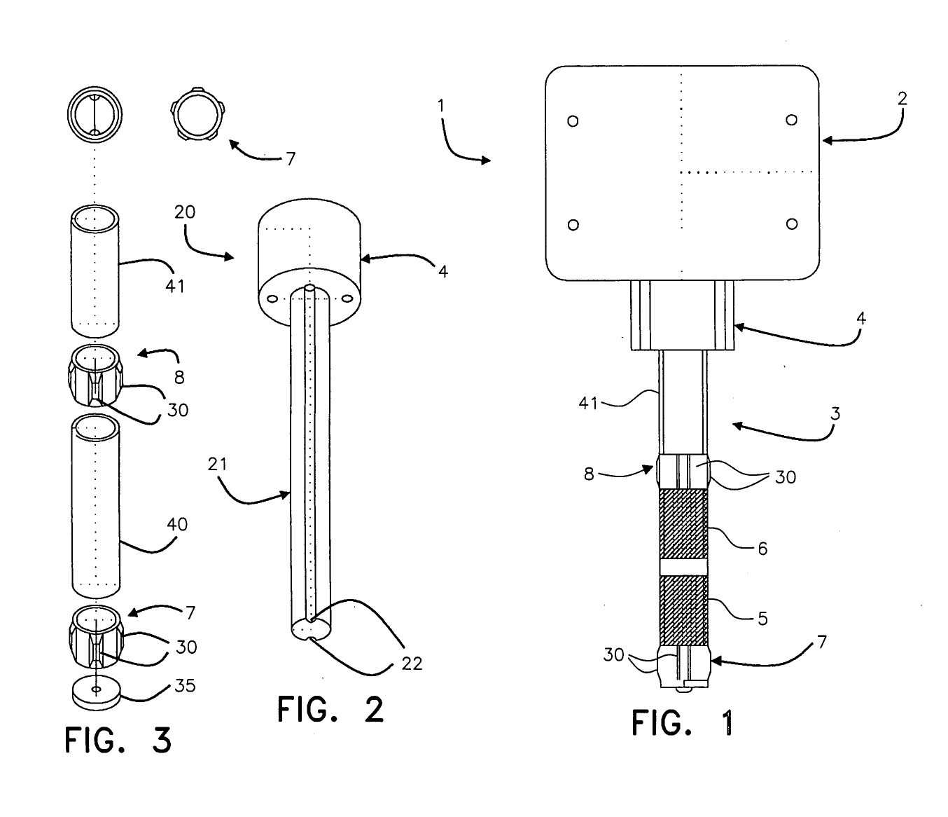

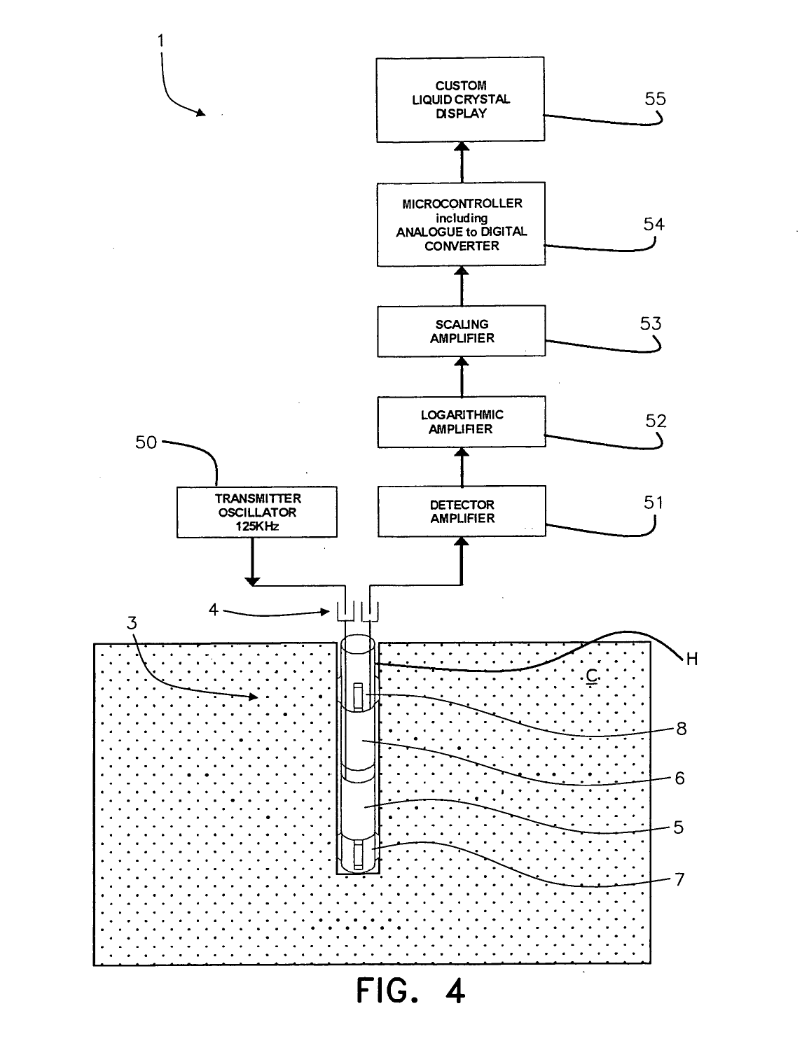

Referring to FIGS. 1 to 4 a moisture meter 1 comprises a housing 2 containing electronic circuits and supporting a digital display (not shown) and a probe 3 having a plug 4 which is inserted into the housing 2.

The probe 3 comprises leading and trailing annular electrodes 5 and 6, and leading and trailing annular spacers 7 and 8. These components are around a stalk 21 having a pair of opposed elongate grooves 22 for wiring. The spacers 7 and 8 have resilient ridges 30 extending radially.

The electrodes 5 and 6 are in the form of conductive foil wrapped around a sleeve-shaped former 40. Also, there is a spacer sleeve 41 between the trailing spacer 8 and the shoulder 4. All of the annular components on the stalk 21 are retained in place by an end washer 35.

The stalk 21 has dimensions of 11.4 mm diameter, 95 mm long, and it is integral with a 30 mm diameter, 20 mm long, base mounting section 4. The stalk 21 includes the two longitudinal wiring grooves 22, 180° apart, which continue as holes through the base section 2. These grooves ensure that the stray capacitance between two wires connecting the two electrodes to the electronics, via a 2 way plug/socket, is maintained at a minimum and stable value.

As shown in the drawings, there are four hollow cylindrical plastics components that are slid over the stalk 21 and retained by a small circular closing plate or washer 35 which is secured to the end centre of the stalk 21 by a single plastics screw.

The two 20 mm wide copper tape electrodes 5 and 6 are wrapped and adhered to the outer surface of the electrode former 40 and spaced apart by 5 mm. The top end of the upper electrode 6 is soldered to one of the connecting wires and the bottom end of the lower electrode 5 is soldered to the other wire.

Because the ridges 30 extend along the axial direction and because they are of a resilient plastics material they act in use to centralise the probe 3 within a blind hole into which the probe 3 is inserted and establish a concentric air gap between the wall of the blind hole and the electrodes 5 and 6.

The base section 4 is plugged onto, and/or mechanically fixed, to the electronics box 2 within which is mounted a single surface mount printed circuit board that contains all of the electronic components including custom-designed liquid crystal display (LCD) and battery power supply.

As shown in FIG. 4 the electronic circuits comprise:
a 125 kHz oscillator 50 driving the electrodes 5 and 6,
a detector amplifier 51 receiving signals from the electrodes 5 and 6;
logarithmic and scaling amplifiers 52 and 53;
a microcontroller 54 with an A/D converter; and
a liquid crystal display 55.

FIG. 4 also diagrammatically shows the probe 3 inserted in a blind hole H in concrete C of 16 mm diameter and 150 mm deep.

The housing 2 contains a battery, LCD display and the electronic circuits which create an alternating electric field between the electrodes and, by detecting the value of the current caused by the alternating electric field, determine the moisture content. The processed value is presented on the LCD display 55.

The capacitance between the probe electrodes is governed by the dielectric constant of the concrete surrounding the probe, which is in turn dependent on the moisture content of the concrete.

The transmitter oscillator circuit 50 provides a constant frequency/constant amplitude 125 KHz unity mark space square wave to drive the transmitter electrode which creates an alternating electric field between the electrodes. This causes a very small AC current flow through the concrete around the probe and into the receiving electrode. An operational amplifier IC configured as a precision half wave rectifier/amplifier detects and amplifies the AC current and outputs a voltage which is proportional to the moisture content of the sample.

Logarithmic Amplifier 52

The purpose of the logarithmic amplifier is to convert the exponentially proportional voltage output of the detector/amplifier to follow a linear relationship with respect to % moisture. An additional benefit is that the entire dynamic range of the detector/amplifier can be used, i.e., the measurement range is increased.

Microcontroller 54

The instrument is powered by a 9 volt PP3 size Alkaline primary battery which drives a low drop out (LDO), low quiescent current regulator IC to provide a stabilised 5 volt supply for the microcontroller. In the OFF condition, the microcontroller goes into a “sleep” mode and in consequence the total supply current drain is only a few microamps. When the ON/OFF button is pressed it interrupts the “sleep” mode and wakes up the microcontroller which then:
Switches on the 5 volt supply to all the external circuits.
Starts a timer module on a 2 minute supply timeout sequence.
Checks the battery low voltage detector input and if low (less than 6 volts) issues a low battery warning on the LCD display.
Starts a 0.25 second repetitive loop to read the internal A/D converter, and drive the LCD display.
Switch to “sleep” mode, i.e. OFF, if the ON/OFF button is pressed before 2 minute timeout.

LCD 55

The LCD displays the 2 digit (including decimal point) moisture values and low battery warning legend.

When carrying out humidity tests in concrete floor slabs drying from the top surface only it has been established that 40% of the slab depth is the equilibrium relative humidity. In other words, if the slab is covered by an impervious floor covering, the relative humidity at 40% of the depth immediately before covering is the relative humidity value that the rest of the slab will reach after the covering has been in place for an extended period of time.

Since the relative humidity is an indication of the moisture content of the concrete, it is also true to say that the moisture content at 40% of the slab depth before covering is the moisture content that will exist throughout the slab after covering for an extended period of time.

This is the basis used for initial calibration data for the meter 1. It is calibrated by checking the top layer of the concrete using the Tramex CME4™ instrument and adjusting to the same value at 40% of the slab depth. More detailed calibration data is obtained by casting a considerable number of small concrete slabs and covering for extended periods of time when various surface moisture contents have been reached.

In use, in one example a 16 mm diameter hole is drilled in the concrete 150 mm deep. The probe 3 is inserted, so that the shoulder 4 abuts the mouth and seals the hole. The circuit operates to drive an electrode 5, while the detector 51 receives the corresponding AC signal on the other electrode 6 to implement a capacitive sensing technique to make below-the-surface measurements of moisture content via a pre-drilled hole in the concrete to be tested. A concrete surface presents a random distribution of its varied constituents, each of which possesses different dielectric and conductive properties. Additionally, the surface is rough. Thus, to obtain accurate and repeatable below-the-surface measurements of moisture content, the probe structure is designed such that a small concentric air gap is established between the electrodes and the concrete surface of the blind hole. This prevents the rough concrete surface making direct contact with the electrodes and thus minimises surface particles of high dielectric constant and/or partially conductive particles, causing erroneous readings. The air gap in conjunction with the large area electrodes enables a uniformly distributed alternating electric field to penetrate into the concrete.

The two dielectric spacers 7 and 8 with longitudinal resilient ridges 30 raised above the surface of the electrodes are a low friction fit within the hole in the concrete and thus centralise the probe and establish the required small concentric air gap. This gap is preferably about 2 mm to 3 mm in the radial dimension.

It will be appreciated that the invention provides a very simple and robust moisture meter for use in detecting moisture beneath the surface. It is able to use well established electronics processing circuits, but avoids the unreliability problems of the prior RH meters.

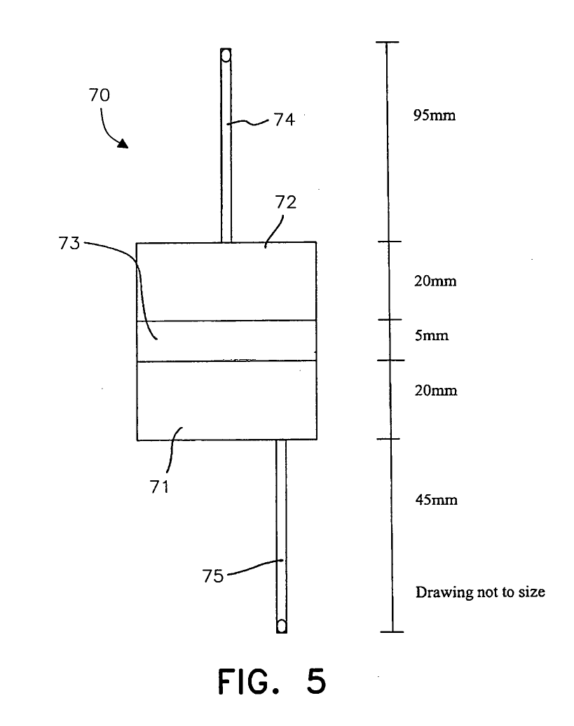

The number and form of dielectric ridged spacers is not limited to those illustrated. For example, the spacers could be moulded from a suitable rubber or resilient plastic with the ridges taking the form of a coarse thread or a tubular plastic spring. Similarly, whilst the embodiment above uses adhesive copper tape electrodes, versions may use flexible printed circuit or electro-plated electrodes. Referring to FIG. 5 an alternative electrode arrangement is shown. An electrode assembly 70 has a flexible circuit board on which are leading and trailing electrodes 71 and 72, with exposed circuit board 73 in-between. Electrical leads 74 and 75 extend from the electrodes 72 and 71 respectively.

These electrodes can be fitted to a 14 mm diameter cylindrical shaft, and they wrap around the shaft with adhesive on the back with can be removed to stick the assembly to the shaft. The board is a single-sided construction having a covercoat, adhesive, copper, adhesive, base laminate, and adhesive on the bottom which could be removed if possible.

The electrodes 72 and 71 have full copper across the face (44 mm×20 mm) with a tab to be 3 mm wide with a track of 0.5 mm down the center. They are stiffened at the ends for soldering purposes based on standard PCB through hole size. There is a 5 mm spacing (no copper) 73 between the electrodes, the spacing just base laminate and covercoat.

The board is a single-layer flexible circuit 50 μm thick and of polyimide, clad on one side with 35 μm copper. The electrodes 71 and 72 are protected by a bonded 50 μm polyimide cover layer, locally rigidised with 125 μm polyimide. There is a self-adhesive backing with peel-off liner: 3M 467MP™ or equivalent.

The invention is not limited to the embodiments described but may be varied in construction and detail. For example, the oscillator may be of a frequency other than 125 kHz. Also, it is not essential that the probe be separable from the housing, as they could integral. All of the dielectric parts may be machined and/or injection moulded or be manufactured by any other suitable process. The probe may be further enhanced by covering the exposed electrode surfaces with a thin insulating coating to provide corrosion protection and to further reduce the risk of damp dust particles causing measurement errors.

1. A moisture meter comprising:
an elongate probe supporting at least one pair of electrodes, and being configured for insertion into bulk material;
a transmitter for driving an electrode;
a detector for receiving current signals of an electrode;
a controller for controlling drive of the electrodes and for processing detected signals to provide a moisture reading; and
wherein there are at least two axially separated radial spacers having formations extending radially to an extent greater than the electrodes, the spacer formations being configured to centralise the probe and to provide a gap between the electrodes and bulk material when the probe is inserted in a hole in the bulk material.

2. The moisture meter as claimed in claim 1, wherein the spacer formations are configured to provide a low friction fit within a hole in the bulk material.

3. The moisture meter as claimed in claim 1, wherein the spacer formations are configured to provide a low friction fit within a hole in the bulk material; and wherein the formations are ridges extending substantially parallel to an axis of the probe.

4. The moisture meter as claimed in claim 1, wherein the formations are ridges extending substantially parallel to an axis of the probe; and wherein there are at least four ridges on each spacer.

5. The moisture meter as claimed in claim 1, wherein there is a leading spacer on a leading side of a first electrode and a trailing spacer at a trailing side of a second electrode.

6. The moisture meter as claimed in claim 1, wherein the transmitter is connected to an electrode by a wire running along a groove in the probe.

7. The moisture meter as claimed in claim 1, wherein the detector is connected to an electrode by a wire running along a groove in the probe.

8. The moisture meter as claimed in claim 1, wherein the transmitter is connected to an electrode by a wire running along a groove in the probe; wherein the detector is connected to an electrode by a wire running along a groove in the probe; and wherein the grooves are diametrically opposed.

9. The moisture meter as claimed in claim 1 wherein the probe comprises a stalk and the electrodes and the spacers are mounted on the stalk.

10. The moisture meter as claimed in claim 1, wherein the controller drives the electrodes with a constant frequency and constant amplitude signal.

11. The moisture meter as claimed in claim 1, wherein the controller drives the electrodes with a constant frequency and constant amplitude signal; and wherein the drive signal is a unity mark space square wave.

12. The moisture meter as claimed in claim 1, wherein the controller drives the electrodes with a constant frequency and constant amplitude signal; and wherein the controller comprises a half wave rectifier/amplifier to detect and amplify received AC current and output a voltage proportional to moisture content.

13. The moisture meter as claimed in claim 1, wherein the controller comprises a logarithmic amplifier to provide a linear output.

14. The moisture meter as claimed in claim 1, wherein the electrodes are of copper foil material.

15. The moisture meter as claimed in claim 1, wherein the electrodes are on a former on the probe.

16. The moisture meter as claimed in claim 1, wherein the electrodes are on a former on the probe; and wherein the former axially abuts a spacer having a shoulder configuration to cover over a hole into which the probe is inserted.

17. The moisture meter as claimed in claim 1, wherein the electrodes are conductors on a printed circuit board which is flexible and is wrapped around a former.

18. The moisture meter as claimed in claim 1, wherein the electrodes include a protective insulation material coating.
